(19) United States
(12) Patent Application Publication
(10) Pub. No.: US 2026/0158612 A1
(43) Pub. Date: Jun. 11, 2026

(54) CHEMICAL MECHANICAL POLISHING (CMP) SYSTEM WITH HIGH UNIFORMITY

(71) Applicant: Taiwan Semiconductor Manufacturing Company, Ltd., Hsinchu (TW)

(72) Inventors: Te-Chien Hou, Kaohsiung (TW); Chi-hsiang Shen, Tainan (TW); Jeng-Chi Lin, Hsinchu (TW); Jui Yu Pai, Hsinchu (TW); Chin-Ming Kuo, Hsinchu (TW); Hsun-Hao Hsu, Hsinchu (TW); Shich-Chang Suen, Shich-Chang (TW)

(21) Appl. No.: 18/977,821

(22) Filed: Dec. 11, 2024

(51) Int. Cl. B24B 37/24; H01L 21/306

(52) U.S. Cl. CPC B24B 37/24; H10P 52/402

(57) ABSTRACT

A chemical mechanical polishing (CMP) polishing pad is provided. The CMP polishing pad includes a pad body characterized by a top surface and a bottom surface and comprising a plurality of voxels. The plurality of voxels comprises: a first portion of the plurality of voxels occupied by a first material; and a second portion of the plurality of voxels occupied by a second material.

### FIELD

Embodiments of the present disclosure relate generally to Chemical Mechanical Polishing (CMP), and more particularly CMP polishing pads with high uniformity.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area.

While some integrated device manufacturers (IDMs) design and manufacture integrated circuits (IC) themselves, fabless semiconductor companies outsource semiconductor fabrication to semiconductor fabrication plants or foundries. Semiconductor fabrication consists of a series of processes in which a device structure is manufactured by applying a series of layers onto a substrate. This involves the deposition and removal of various dielectric, semiconductor, and metal layers. The areas of the layer that are to be deposited or removed are controlled through photolithography. Each deposition/removal process is generally followed by cleaning as well as inspection steps. Therefore, both IDMs and foundries rely on numerous semiconductor equipment and semiconductor fabrication materials, often provided by vendors. There is always a need for customizing or improving those semiconductor equipment and semiconductor fabrication materials, which results in more flexibility, reliability, and cost-effectiveness.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram illustrating an example CMP system in accordance with some embodiments.

FIG. 2 is a diagram illustrating principles of a polishing pad in accordance with some embodiments.

FIG. 3 is a top view of the polishing pad shown in FIG. 2 in accordance with some embodiments.

FIG. 4 is a diagram illustrating fabricating a polishing pad using 3D printing in accordance with some embodiments.

FIG. 5A is a diagram illustrating a continuous mode of applying additive to a polishing pad in accordance with some embodiments.

FIG. 5B is a diagram illustrating a pulse mode of applying additive to a polishing pad in accordance with some embodiments.

FIG. 6 is a diagram is a diagram illustrating a CMP system in accordance with some embodiments.

FIG. 7 is a flowchart diagram illustrating an example method 700 for operating a CMP system in accordance with some embodiments.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, source/drain region(s) may refer to a source or a drain, individually or collectively dependent upon the context. For example, a device may include a first source/drain region and a second source/drain region, among other components. The first source/drain region may be a source region, whereas the second source/drain region may be a drain region, or vice versa. One of ordinary skill in the art would recognize many variations, modifications, and alternatives.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

### Overview

Chemical Mechanical Polishing (CMP) is a critical process used in semiconductor manufacturing to achieve the necessary planarity and smoothness of the wafer surfaces. This process is particularly vital in the fabrication of integrated circuits (ICs) and other microelectronic devices, where even minor surface irregularities can lead to significant performance issues or defects. CMP combines both chemical and mechanical forces to remove material from a wafer surface. CMP is commonly used in various applications, such as planarization for subsequent photolithography and etching steps, interlayer dielectric (ILD) planarization, trench planarization for shallow trench isolation (STI), metal polishing, and the like.

CMP typically involves the following components: abrasive slurry (or simply “slurry”), a CMP polishing pad (or simply a “polishing pad”), and a carrier head (e.g., a rotating wafer holder). Abrasive slurry is a mixture of abrasive particles suspended in a chemical solution and plays a dual role, namely providing the mechanical action through the abrasive particles and the chemical action through the solution, which reacts with the wafer material to facilitate its removal. The carrier head holds the wafer in place and applies pressure, ensuring uniform contact between the wafer and the polishing pad.

The wafer is placed on a rotating polishing pad, which provides the mechanical force necessary to achieve the desired planarity. The polishing pad can be made from various materials. However, there are some challenges related to the polishing pad and the CMP system. One of those is the thickness variations within a die (“WiD”) or within a wafer (“WiW”).

As the semiconductor technology nodes advance to 5 nm (“Node 5”) and beyond, WiD uniformity and WiW uniformity become more demanding than ever before. WiW uniformity refers to the consistency of characteristics across the entire wafer. A wafer can contain hundreds or thousands of dies, and WiW uniformity measures how similar these dies are to each other. High WiW uniformity ensures that the performance and yield of dies across the wafer are consistent. This is important for manufacturing efficiency and cost-effectiveness, as significant variations across a wafer can lead to lower yields and increased production costs. On the other hand, WiD uniformity refers to the consistency of characteristics (such as thickness, doping levels, electrical properties, etc.) within a single die on a semiconductor wafer. A die is a small block of semiconducting material on which a given functional circuit is fabricated. High WiD uniformity ensures that the performance and reliability of the circuit elements within a single die are consistent. This is crucial for the functionality of the final semiconductor device, as variations within a die can lead to defects and operational issues.

Traditional CMP polishing pads are formed by one material. When priming abrasive slurry with additives (e.g., inhibitor, enhancer, surfactant, etc.) on the CMP polishing pad, additive distribution is uneven due to various factors, such as the flow field, the pressure between the wafer and the CMP polishing pad, and the temperature. The uneven distribution of additives results in the thickness variations within a die or within a wafer. Therefore, there is a need for a CMP system having improved WiD or WiW uniformity.

In accordance with some aspects of the disclosure, a novel CMP polishing pad is provided. The novel CMP polishing pad is fabricated using 3D printing. Unlike a conventional polishing pad, which is formed by a single material, the polishing pad 200 according to some embodiments of the present application comprises at least a first material and a second material. The first material is a positively-charged material, and the second material is a negatively-charged material. The positively-charged material and the negatively-charged material are not evenly distributed in the polishing pad. For instance, the positively-charged material is distributed unevenly, accumulating more at certain regions than others. As a result, negatively-charged additive (e.g., negatively-charged inhibitor, negatively-charged enhancer, or negatively-charged surfactant) is attracted to the top surface unevenly. At regions where a higher distribution density of the negatively-charged additive is desired, more negatively-charged additive is attracted, thereby enabling the redistribution or rebalancing of the negatively-charged additive. The WiD or WiW thickness uniformity accordingly can be enhanced. Moreover, a separate supply equipment, in addition to an abrasive slurry supply equipment, enables flexibly applying the additive to desired regions of the polishing pad, thereby improving thickness uniformity.

### Exemplary CMP System

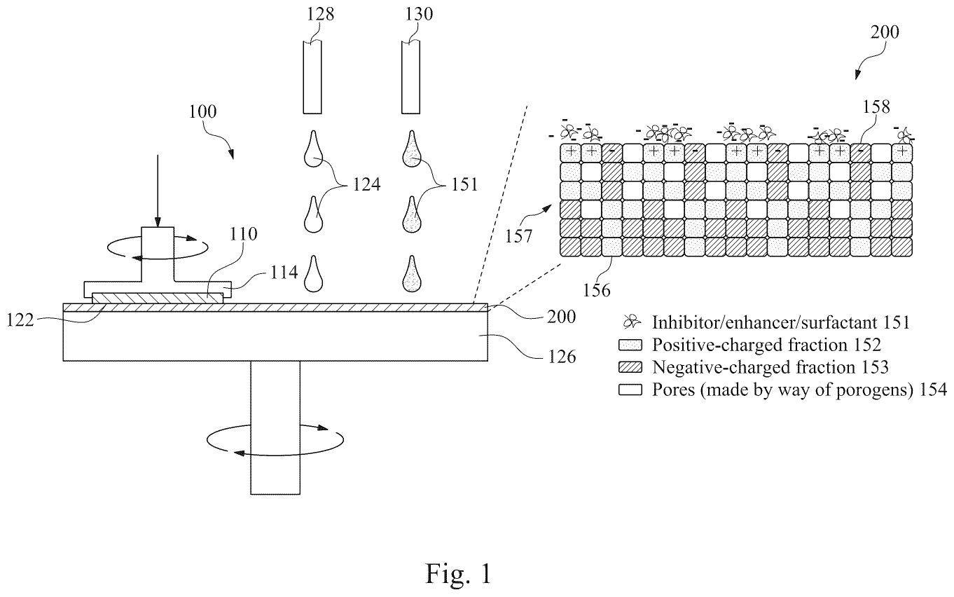

FIG. 1 is a block diagram illustrating an example CMP system 100 in accordance with some embodiments. In the example shown in FIG. 1, the CMP system (or “CMP apparatus”) 100 includes, among other components, a rotating wafer holder 114, a polishing pad 200, a rotating platform 126, an abrasive slurry supply equipment 128, and an additive supply equipment 130. The rotating wafer holder 113 is operable to hold a wafer 110 to be subject a CMP process and rotate along an axis (which extends in a vertical direction, as shown in FIG. 1).

On the other hand, the polishing pad 200 is mounted to the rotating platform 126 by one or more adhesives (e.g., double-sided adhesive tapes, pressure-sensitive adhesives, epoxy adhesives, silicone adhesives, hot melt adhesives, contact adhesives, etc.). These adhesives ensure that the polishing pad 200 remains securely attached to the rotating platform 126 during the CMP process, allowing for consistent and reliable wafer planarization. The rotating platform 126 is operable to rotate along an axis (which extends in a vertical direction, as shown in FIG. 1). The rotational speed of the rotating platform 126 is different from that of the rotating wafer holder 113. In addition, although the axis of rotation of the rotating platform 126 and the axis of rotation of the rotating wafer holder 113 are not collinear, the axes are generally parallel.

The polishing pad 200 is applied to the wafer surface 122 at a specific pressure. As the CMP process combines both chemical and mechanical forces to remove material from the wafer surface 122, the necessary planarity and smoothness of the wafer surface 122 can be achieved.

The polishing pad 200 is a consumable item. Under normal wafer fabrication conditions, the polishing pad is replaced after a certain amount of usage time. The polishing pads 112 may be hard, incompressible pads or soft pads. For oxide polishing, hard and stiffer pads are generally used to achieve planarity. Softer pads are generally used in other polishing processes to achieve improved uniformity and smooth surfaces. The hard pads and the soft pads may also be combined in an arrangement of stacked pads for customized applications.

The abrasive slurry supply equipment 128 is disposed over the polishing pad 200. In one example, the abrasive slurry supply equipment 128 is a feed or an arm connected to a tank accommodating abrasive slurry to be used during the CMP process. When the CMP system 100 is in operation, the abrasive slurry supply equipment 128 is operable to dispense abrasive slurry 124 onto the polishing pad 200, and the abrasive slurry 124 is distributed on the polishing pad 200 due to the rotation of the rotating platform 126 (and therefore the rotation of the polishing pad 200).

The additive supply equipment 130 is disposed over the polishing pad 200. In one example, the additive supply equipment 130 is a feed or an arm connected to a tank accommodating a type of additive to be used during the CMP process. When the CMP system 100 is in operation, the additive supply equipment 130 is operable to dispense the additive 151 onto the polishing pad 200, and the additive 151 is distributed on the polishing pad 200 due to the rotation of the rotating platform 126 (and therefore the rotation of the polishing pad 200). As will be discussed in greater detail below, having a separate supply equipment (i.e., the additive supply equipment 130) enables flexibly applying the additive to desired regions of the polishing pad 200, thereby improving thickness uniformity.

The additive may be one or more of the following: enhancers, inhibitors, and surfactants, each playing a crucial role in optimizing the planarization process. The right combination of enhancers, inhibitors, and surfactants is crucial for optimizing the CMP process, achieving the desired level of planarization, and minimizing defects. Effective use of CMP additives helps in achieving better within die (WiD) and within wafer (WiW) uniformity, which directly impacts the yield and performance of semiconductor devices. Improved CMP processes lead to higher manufacturing efficiency and reduced costs, which is essential in the competitive semiconductor industry. The CMP system therefore is capable of handling enhancers, inhibitors, and surfactants (or other clean chemical).

Enhancers are chemical agents added to the CMP slurry to boost the material removal rate (RR) and enhance the efficiency of the planarization process. They facilitate and accelerate the chemical reactions between the slurry and the wafer surface. Common enhancers include oxidizers like hydrogen peroxide (H₂O₂) and potassium iodate (KIO₃), which promote the oxidation of the wafer surface, making it easier to remove material.

Inhibitors, also known as corrosion inhibitors, are added to CMP slurries to prevent excessive removal or damage to certain areas of the wafer, ensuring selective and controlled material removal. Benzotriazole (BTA) is a commonly used inhibitor that helps protect copper surfaces during CMP.

Surfactants are surface-active agents that help in stabilizing the slurry and improving its distribution across the wafer surface. They reduce surface tension, allowing for better wetting and uniformity of the slurry. Common surfactants include nonionic surfactants like polyethylene glycol (PEG) and anionic surfactants like sodium dodecyl sulfate (SDS).

As shown in the enlarged illustration of the polishing pad 200 at the right side of FIG. 1, the polishing pad 200 includes a pad body 157 that is cylindrical structure having a bottom surface 156 and a top surface 158. The top surface 158 is in contact with the wafer 110 during the CMP process. The bottom surface 156 is the surface of the polishing pad 200 that is in contact with the rotating platform 126.

Although not shown in FIG. 1, the polishing pad 200 may, in some embodiments, further include grooves disposed at the top surface 158. These grooves are channels that horizontally run through a top portion of the pad body 157 and allow for the flow of abrasive slurry 124 during the CMP process. The grooves allow for evenly distributing the abrasive slurry 124 across the polishing pad 200 (and therefore the wafer surface 122). In one example, the grooves are arranged in the following manner: a first set of parallel grooves extend in a first horizontal direction, and as second set of parallel grooves extend in a second horizontal direction perpendicular to the first horizontal direction. One of ordinary skill in the art would recognize many variations, modifications, and alternatives.

Unlike a conventional polishing pad, which is formed by a single material, the polishing pad 200 according to some embodiments of the present application comprises at least a first material and a second material. The first material is a positively-charged material 152, and the second material is a negatively-charged material 153. The positively-charged material 152 and the negatively-charged material 153 are not evenly distributed in the polishing pad 200.

As shown in FIG. 1, the pad body 157 comprises multiple (e.g., thousands, millions) voxels. Voxels are the three-dimensional equivalent of pixels. While pixels represent individual points in a two-dimensional image, voxels represent individual points in a three-dimensional space. In 3D printing, voxels are used to define the shape and structure of objects to be printed.

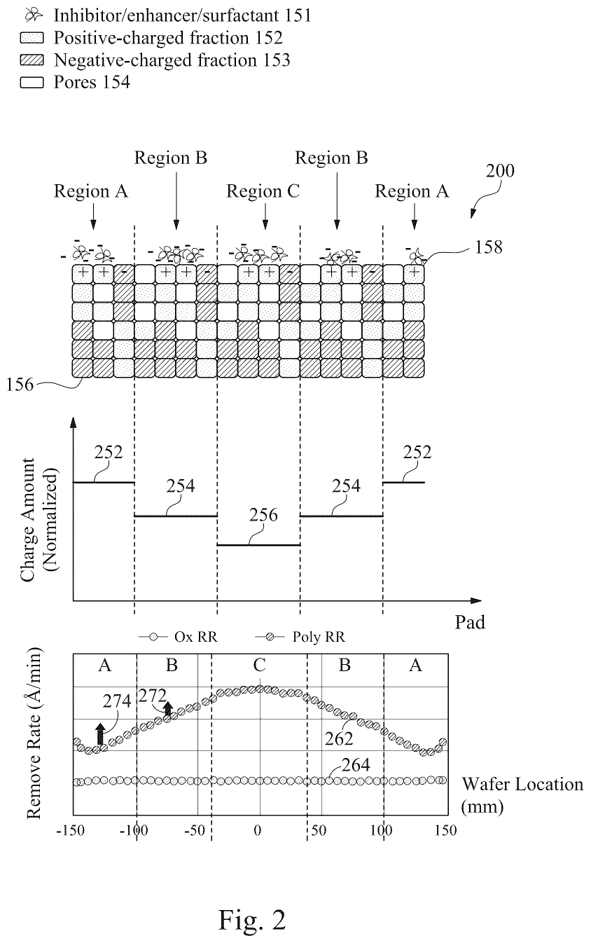

In the example shown in FIG. 1, a first portion of the voxels are occupied by the first material (e.g., positively-charged material 152), and a second portion of the voxels are occupied by the second material (e.g., negatively-charged material 153). At the top surface 158, the positively-charged material 152 is distributed unevenly, accumulating more at certain regions than others. As a result, negatively-charged additive (e.g., negatively-charged inhibitor, negatively-charged enhancer, or negatively-charged surfactant) 151 is attracted to the top surface 158 unevenly. At regions where a higher distribution density of the negatively-charged additive 151 is desired, more negatively-charged additive 151 is attracted, thereby enabling the redistribution or rebalancing of the negatively-charged additive 151. The WiD or WiW thickness uniformity can be enhanced. This operational principle will be described in greater detail below with reference to FIG. 2.

Although the positively-charged material 152, in the example shown in FIG. 1, operates to modify or manipulate the redistribution or rebalancing of the negatively-charged additive 151, the negatively-charged material 153 is also important in terms of keep the electric neutrality of the polishing pad 200. Electric neutrality refers to a state where the total positive charge is equal to the total negative charge within a material, system, or structure. In other words, the net electrical charge is zero. This concept is crucial in various fields of science and engineering to ensure stability and prevent undesirable electrostatic interactions. In the example shown in FIG. 1, the total amount of positive charges carried by the positively-charged material 152 is equal to the total amount of negative charges carried by the negatively-charged material 153.

In some embodiments, the polishing pad 200 may further include pores 154 distributed across the pad body 157. In some examples, the density of pores 154 close to the top surface 158 is higher than the density of pores 154 close to the bottom surface 156. In other words, the density of pores 154 decreases from the top surface to the bottom surface 156. Since the pores 154 do not carry any charges, they do not impact the electric neutrality of the polishing pad 200 described above. The pores 154 can facilitate the flowing of the abrasive slurry 124 and the additive 151.

In one implementation, the polishing pad is fabricated by 3D printing. FIG. 4 is a diagram illustrating fabricating a polishing pad using 3D printing in accordance with some embodiments. 3D printing is a process of creating three-dimensional objects from a digital file. This is achieved by layering materials in successive layers until the desired object is formed. The technology encompasses various methods and materials, including plastics, metals, and ceramics. A typical process of 3D printing involves, among other steps, the following steps. A digital 3D model is first created using computer-aided design (CAD) software. The 3D model is then converted into thin, horizontal layers using slicing software. The resulting file contains instructions for the 3D printer. The 3D printer reads the sliced file and deposits material layer by layer to build the object. Any necessary finishing steps, such as removing support structures, sanding, or painting, are subsequently performed.

In the example shown in FIG. 4, the 3D printer 400 includes a gantry 402 and three nozzles, namely a first nozzle 412, a second nozzle 413, and a third nozzle 414. The first nozzle 412 is configured to deliver the positively-charged material 152. The second nozzle 412 is configured to deliver the negatively-charged material 153. The third nozzle 414 is configured to deliver the porogen 155.

The porogen 155 is a material that is incorporated into a 3D printing process to create pores or voids within the final printed structure. After the printing process, the porogen 155 is typically removed, leaving behind a porous architecture (e.g., the pore 154). This technique is often used to manufacture materials with specific characteristics, such as increased surface area, reduced weight, or enhanced biological integration. Porogens 155 can be classified based on their physical or chemical nature, and their method of removal. Solid porogens are physically mixed with the primary printing material. Examples include salts, sugars, or polymer beads. After printing, these solid porogens are dissolved or leached out using appropriate solvents. Gaseous porogens involve the generation of gas bubbles within the printing material, often through chemical reactions or physical processes like foaming agents. Once the gas escapes, it leaves behind a porous structure. Liquid porogens are typically immiscible liquids that can be removed through washing or evaporation processes.

Voxel-level control of the 3D printer 400 can be achieved by techniques such as digital light process (DLP), stereolithography (SLA), binder jetting, and the like. In DLP, DLP projectors use a digital micromirror device (DMD) to control the exposure of light to a photopolymer resin. By precisely controlling the individual mirrors, the shape and structure of the printed object can be manipulated at a voxel-level. Some DLP systems can modulate the intensity of light exposure for each voxel, allowing for variations in material properties within the printed object. In SLA, SLA machines can be programmed to control the exposure time for individual voxels within the resin tank, enabling more complex structures and gradients in material properties. By using different types of resin or varying exposure times for different voxels, SLA can produce objects with multiple materials or properties within a single print. In binder jetting, binder jetting printers deposit a binder onto a bed of powder. By controlling the placement and amount of binder at the voxel level, intricate structures and variations in material properties can be created. One of ordinary skill in the art would recognize many variations, modifications, and alternatives.

As to charged materials (e.g., the positively-charged material 152 and the negatively-charged material 153), various types of materials, such as polymers, nanomaterials, can be considered. Polymers can be functionalized to carry positive or negative charges. For example, polyelectrolytes are polymers with ionizable groups that can dissociate in aqueous solutions, leaving the polymer chain charged. Nanoparticles, nanotubes, and nanofibers can be surface-modified to carry charges. These materials are often used to enhance the mechanical strength, electrical conductivity, or biological activity of the printed object. Some examples of positively-charged materials may comprise polyethylenimine (PEI), chitosan, quaternary ammonium compounds, polydiallyldimethylammonium chloride (PDADMAC), Poly-L-lysine (PLL). Some examples of negatively-charged materials may comprise polyacrylic acid (PAA), carboxymethyl cellulose (CMC). These materials can be used in conjunction with polyurethane or Polyvinyl Alcohol (PVA), which are commonly used as the material for a CMP polishing pad. One of ordinary skill in the art would recognize many variations, modifications, and alternatives.

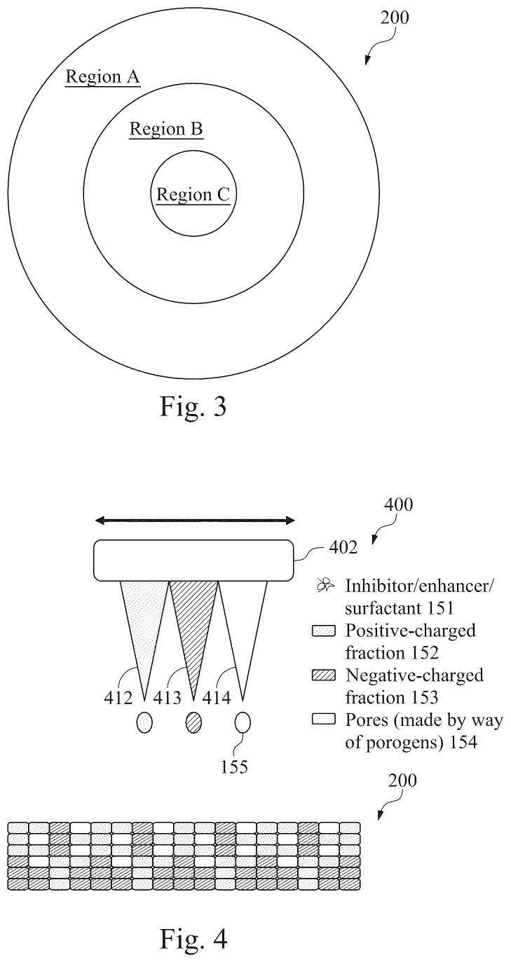

FIG. 2 is a diagram illustrating principles of a polishing pad in accordance with some embodiments. In the example shown in FIG. 2, the polishing pad 200 includes three regions, namely Region A, Region B, and Region C. FIG. 3 is a top view of the polishing pad shown in FIG. 2 in accordance with some embodiments. In the example shown in FIG. 3, Region A, Region B, and Region C are concentric. Region C is at the center of the polishing pad 200, while Region A is at the periphery of the polishing pad 200. Region B is in the middle and between Region A and Region C.

Now referring back to FIG. 2, without the positively-charged material 152, the remove rate of different materials (e.g., oxide and polysilicon) vary dramatically at different wafer locations (i.e., the location of the wafer 110 across the polishing pad 200) due to the uneven distribution of additive 151 on the top surface of the polishing pad 200. As shown in FIG. 2, the remove rate of the polysilicon is nearly constant at various wafer locations, whereas the remove rate of oxide is the highest at Region C and the lowest at Region A. As a result, the selectivity between oxide and polysilicon (i.e., the ratio of oxide removal rate to polysilicon removal rate) is the highest at Region C and the lowest at Region A. The variation in selectivity results in variation in thickness. Thus, it is desired to have a relatively flat selectivity curve across the polishing pad 200.

To address this selectivity variation, the polishing pad 200 is designed to have unevenly distributed positively-charged material 152. Specifically, Region A has a first charge amount, Region B has a second charge amount, and Region C has a third charge amount. The first charge amount is larger than the second charge amount, and the second charge amount is larger than the first charge amount. In one example, the first charge amount is 50% after normalization, the second charge amount is 30% after normalization, and the third charge amount is 20% after normalization. It should be understood that these numbers are exemplary and may be adjusted as needed depending on different selectivity curves. The more the selectivity curve varies, the more the first, second, and third charge amounts vary. One of ordinary skill in the art would recognize many variations, modifications, and alternatives.

As a result, the high charge amount at Region A results in more negatively-charged additive 151 to be attracted to Region A, thereby significantly boosting the removal rate of oxide at Region A (illustrated by the arrow 274 in FIG. 2). Likewise, the removal rate of oxide at Region B is also boosted at Region B, although not as much as at Region A. As such, the removal rate of oxide becomes more uniform across various wafer locations. In short, by using the polishing pad 200, more additive 151 is applied to where additive 151 is otherwise less distributed, and less additive 151 is applied to where additive 151 is otherwise more distributed.

It should be understood that although positively-charged material 152 and negatively-charged additive 151 are used as an illustrative example, the opposite is also possible in other embodiments. In other words, in other embodiments, negatively-charged material is unevenly distributed on the top surface 158 of the polishing pad 200, thereby attracting positively-charged additive 151 accordingly. One of ordinary skill in the art would recognize many variations, modifications, and alternatives.

In addition, as stated above, the additive supply equipment 130 is operable to dispense the additive 151 onto the polishing pad 200. Having a separate supply equipment (i.e., the additive supply equipment 130) enables flexibly applying the additive to desired regions of the polishing pad 200, thereby improving thickness uniformity. Specifically, the additive supply equipment 130 can move, independent of the abrasive slurry supply equipment 128, over the entire polishing pad 200. For example, the additive supply equipment 130 can move to a position within Region A shown in FIG. 2 to further increase the amount of negatively-charged additive 151, thereby ensuring the selectivity becomes nears uniform across the polishing pad 200.

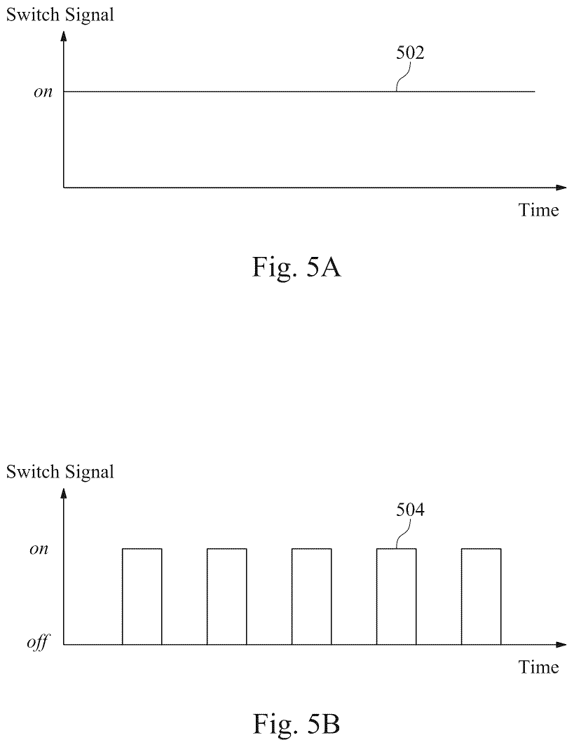

FIG. 5A is a diagram illustrating a continuous mode of applying additive to a polishing pad in accordance with some embodiments. FIG. 5B is a diagram illustrating a pulse mode of applying additive to a polishing pad in accordance with some embodiments. In the example shown in FIG. 5A, the additive 151 is continuously applied through the additive supply equipment 130. The switch signal 502 is a constant ON level. The advantage of the continuous mode includes easy design requirement and high stability.

In the example shown in FIG. 5B, the additive 151 is applied through the additive supply equipment 130 in a pulsed manner. The switch signal 504 alternates between the ON level and the OFF level. Benefits of the pulse mode includes lower defect impact risk and lower cost of additive 151, among other benefits.

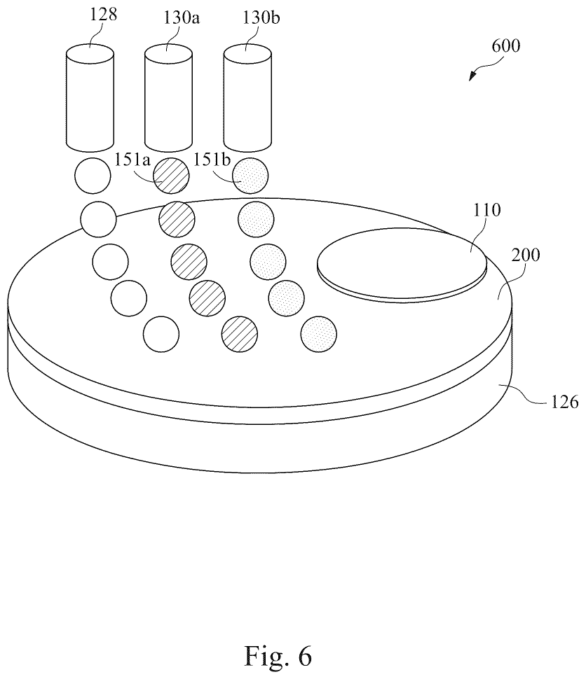

FIG. 6 is a diagram is a diagram illustrating a CMP system 600 in accordance with some embodiments. The CMP system 600 shown in FIG. 6 is similar to the CMP system 100 shown in FIG. 1 except that the CMP system 600 includes two additive supply equipment 130a and 130b (collectively, 130). The additive supply equipment 130a is a feed or an arm configured to deliver a first additive 151a. The additive supply equipment 130b is a feed or an arm configured to deliver a second additive 151b. In one example, the first additive 151a is an enhancer, and the second additive 151b is an inhibitor. In another example, the first additive 151a is a combination of an enhancer and a surfactant, and the second additive 151b is a combination of an inhibitor and a surfactant. One of ordinary skill in the art would recognize many variations, modifications, and alternatives.

It should be understood that the first additive 151a and the second additive 151b may be the same in some embodiments. In other words, the CMP system 600 uses two additive supply equipment 130a and 130b to deliver the additive 151, perhaps one within region A shown in FIG. 2 and the other within Region B shown in FIG. 2. This arrangement is helpful if the area of the polishing pad 200 becomes larger in the future. One of ordinary skill in the art would recognize many variations, modifications, and alternatives.

It should also be understood that although the embodiment of only two additive supply equipment 130a and 130b is shown in FIG. 6, the CMP system 600 may include more than two additive supply equipment 130. In one example, the CMP system 600 may include three additive supply equipment for delivering enhancer, inhibitor, and surfactant, respectively. In another example, the CMP system 600 may include four additive supply equipment, two for delivering enhancer at different locations and two for delivering inhibitor at different locations. One of ordinary skill in the art would recognize many variations, modifications, and alternatives.

It should also be understood that the techniques disclosed herein can be applied to both bulk CMP and buff CMP. Bulk CMP and Buff CMP are two common types of chemical mechanical polishing (CMP) processes used in semiconductor manufacturing. They differ primarily in their application and the specific goals they achieve. The purpose of bulk CMP is to planarize and polish the entire surface of a semiconductor wafer, ensuring a uniform thickness and smooth finish. Bulk CMP is used in various stages of semiconductor manufacturing, including after wafer fabrication and before metallization or patterning.

The purpose of buff CMP, on the other hand, is to electively polish specific areas or features on a wafer, often for creating topographical structures or patterns. A mask or template is used to protect certain areas of the wafer from polishing. The polishing slurry is then applied, targeting only the exposed regions. Buff CMP is used in processes like damascene copper metallization, where trenches or vias are filled with copper and then planarized using buff CMP.

### Exemplary Method for Operating a CMP System

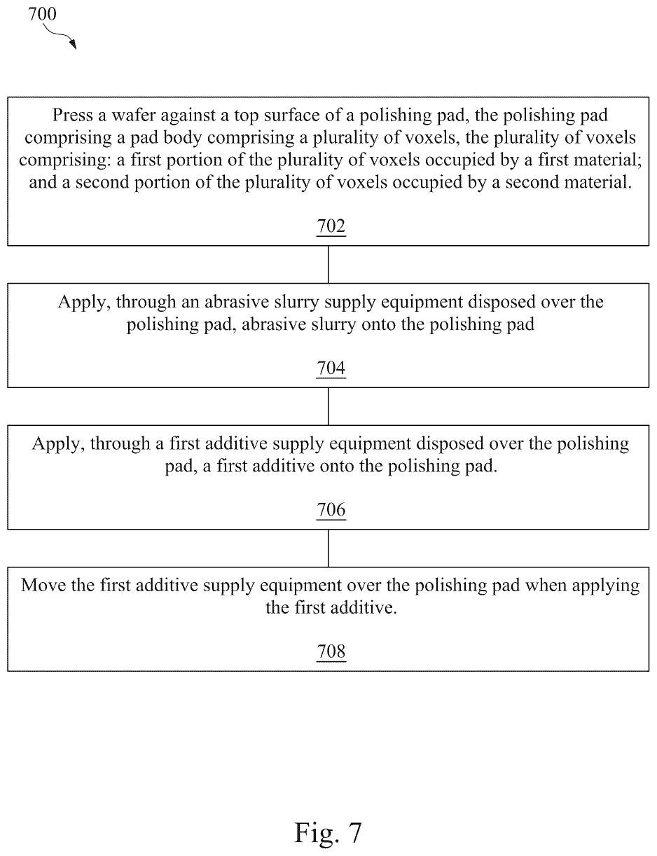

FIG. 7 is a flowchart diagram illustrating an example method 700 for operating a CMP system in accordance with some embodiments. In the example shown in FIG. 7, the method 700 includes operations 702, 704, 706, and 708. Additional operations may be performed. Also, it should be understood that the sequence of the various operations discussed above with reference to FIG. 7 is provided for illustrative purposes, and as such, other embodiments may utilize different sequences. These various sequences of operations are to be included within the scope of embodiments.

At operation 702, a wafer (e.g., the wafer 110 shown in FIG. 1) is pressed against a top surface (e.g., the top surface 158 shown in FIG. 1) of a polishing pad (e.g., the polishing pad 200 shown in FIG. 1). The polishing pad includes a pad body comprising multiple voxels. The voxels comprises: a first portion of the plurality of voxels occupied by a first material (e.g., the positively-charged material 152); and a second portion of the plurality of voxels occupied by a second material (e.g., the negatively-charged material 153).

At operation 704, abrasive slurry (e.g., the abrasive slurry 124 shown in FIG. 1) is applied, through an abrasive slurry supply equipment (e.g., the abrasive slurry supply equipment 128) disposed over the polishing pad, onto the polishing pad.

At operation 706, a first additive (e.g., the additive 151), through a first additive supply equipment (e.g., the additive supply equipment 130) disposed over the polishing pad, is applied onto the polishing pad. In some embodiments, the first additive is applied in a pulsed manner.

At operation 708, the first additive supply equipment is moved over the polishing pad when applying the first additive.

### Summary

In accordance with some aspects of the disclosure, a chemical mechanical polishing (CMP) polishing pad is provided. The CMP polishing pad includes a pad body characterized by a top surface and a bottom surface and comprising a plurality of voxels. The plurality of voxels comprises: a first portion of the plurality of voxels occupied by a first material; and a second portion of the plurality of voxels occupied by a second material.

In accordance with some aspects of the disclosure, a chemical mechanical polishing (CMP) system is provided. The CMP system includes: a polishing pad, an abrasive slurry supply equipment disposed over the polishing pad, and a first additive supply equipment disposed over the polishing pad. The polishing pad includes a pad body characterized by a top surface and a bottom surface and comprising a plurality of voxels. The plurality of voxels comprises: a first portion of the plurality of voxels occupied by a first material; and a second portion of the plurality of voxels occupied by a second material.

In accordance with some aspects of the disclosure, a method of operating a chemical mechanical polishing (CMP) system is provided. The method includes the following steps: pressing a wafer against a top surface of a polishing pad, the polishing pad comprising a pad body comprising a plurality of voxels, the plurality of voxels comprising: a first portion of the plurality of voxels occupied by a first material; and a second portion of the plurality of voxels occupied by a second material; applying, through an abrasive slurry supply equipment disposed over the polishing pad, abrasive slurry onto the polishing pad; and applying, through a first additive supply equipment disposed over the polishing pad, a first additive onto the polishing pad.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chemical mechanical polishing (CMP) polishing pad, comprising:
a pad body characterized by a top surface and a bottom surface and comprising a plurality of voxels, wherein the plurality of voxels comprises:
a first portion of the plurality of voxels occupied by a first material; and
a second portion of the plurality of voxels occupied by a second material.

2. The CMP polishing pad of claim 1, wherein the first material comprises a positively-charged material, and the second material comprises a negatively-charged material.

3. The CMP polishing pad of claim 2, wherein a first total amount of charges carried by the positively-charged material is equal to a second total amount of charges carried by the negatively-charged material.

4. The CMP polishing pad of claim 2, wherein at the top surface of the pad body, the positively-charged material is distributed unevenly.

5. The CMP polishing pad of claim 4, wherein a first region at a center of the top surface is characterized by a first charge amount, and a second region at a periphery of the top surface is characterized by a second charge amount, and the first charge amount is lower than the second charge amount.

6. The CMP polishing pad of claim 5, wherein a third region between the first region and the second region is characterized by a third charge amount, and the third charge amount is higher than the first charge amount but lower than the second charge amount.

7. The CMP polishing pad of claim 6, wherein the pad body comprise a cylindrical plate, and the first region, the third region, and the second region are concentric.

8. The CMP polishing pad of claim 1, wherein the first material comprises a negatively-charged material, and the second material comprises a positively-charged material.

9. The CMP polishing pad of claim 1, wherein the plurality of voxels further comprises a third portion of the plurality of voxels occupied by pores.

10. The CMP polishing pad of claim 9, wherein a density of the pores decreases from the top surface to the bottom surface.

11. A chemical mechanical polishing (CMP) system, comprising:
a polishing pad comprising a pad body characterized by a top surface and a bottom surface and comprising a plurality of voxels, wherein the plurality of voxels comprises:
a first portion of the plurality of voxels occupied by a first material; and
a second portion of the plurality of voxels occupied by a second material;
an abrasive slurry supply equipment disposed over the polishing pad; and
a first additive supply equipment disposed over the polishing pad.

12. The CMP system of claim 11, wherein the first material comprises a positively-charged material, and the second material comprises a negatively-charged material.

13. The CMP system of claim 12, wherein at the top surface of the pad body, the positively-charged material is distributed unevenly.

14. The CMP system of claim 13, wherein a first region at a center of the top surface is characterized by a first charge amount, and a second region at a periphery of the top surface is characterized by a second charge amount, and the first charge amount is lower than the second charge amount.

15. The CMP system of claim 11, wherein the plurality of voxels further comprises a third portion of the plurality of voxels occupied by pores.

16. The CMP system of claim 11, wherein the first additive supply equipment is configured to apply a first additive onto the polishing pad, and wherein the first material comprises a positively-charged material, and the first additive is negatively-charged.

17. The CMP system of claim 11, further comprising:
a second additive supply equipment disposed over the polishing pad and configured to apply a second additive onto the polishing pad.

18. A method of operating a chemical mechanical polishing (CMP) system, comprising:
pressing a wafer against a top surface of a polishing pad, the polishing pad comprising a pad body comprising a plurality of voxels, the plurality of voxels comprising: a first portion of the plurality of voxels occupied by a first material; and a second portion of the plurality of voxels occupied by a second material;
applying, through an abrasive slurry supply equipment disposed over the polishing pad, abrasive slurry onto the polishing pad; and
applying, through a first additive supply equipment disposed over the polishing pad, a first additive onto the polishing pad.

19. The method of claim 18, further comprising:
moving the first additive supply equipment over the polishing pad when applying the first additive.

20. The method of claim 18, wherein applying the first additive comprises:
applying the first additive in a pulsed manner.
